(19) United States
(12) Patent Application Publication
(10) Pub. No.: US 2025/0337210 A1
(43) Pub. Date: Oct. 30, 2025

(54) CHAMBER DEVICE OF GAS LASER APPARATUS, GAS LASER APPARATUS, AND ELECTRONIC DEVICE MANUFACTURING METHOD

(71) Applicant: Gigaphoton Inc., Tochigi (JP)

(72) Inventors: Yoichi YAMANOUCHI, Oyama-shi (JP); Takashi MATSUNAGA, Oyama-shi (JP)

(73) Assignee: Gigaphoton Inc., Tochigi (JP)

(21) Appl. No.: 19/074,094

(22) Filed: Mar. 7, 2025

(30) Foreign Application Priority Data
Apr. 24, 2024 (JP) 2024-070485

(51) Int. Cl. H01S 3/038; G03F 7/20

(52) U.S. Cl. CPC H01S 3/0382; G03F 7/2006; H01S 3/0381

(57) ABSTRACT

A chamber device includes: a chamber body; an anode extending along a Z direction; a cathode disposed in an internal space facing the anode, extending along the Z direction, and including a base part and a discharge part protruding from the base part toward the anode; a cathode-side cover part including a base facing part and covers a part of the base part; a cathode-side acoustic absorbing member disposed in a space between the cathode-side cover part and the base part; and an inclined part including an inclined surface disposed in a space closer to the base part than the base facing part in the V direction and closer to the discharge part than the base facing part in the H direction, broadening to an opposite side with respect to the discharge part as the inclined surface is closer to the base part along the V direction, and extending in the Z direction.

### CROSS-REFERENCE TO RELATED APPLICATIONS

The present application claims the benefit of Japanese Patent Application No. 2024-70485, filed on Apr. 24, 2024, the entire contents of which are hereby incorporated by reference.

### BACKGROUND

### 1. Technical Field

The present disclosure relates to a chamber device of a gas laser apparatus, a gas laser apparatus, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248 nm and an ArF excimer laser apparatus that outputs a laser beam having a wavelength of about 193 nm are used.

Spectral linewidths of spontaneous oscillation beams of the KrF excimer laser apparatus and the ArF excimer laser apparatus are as wide as from 350 μm to 400 μm. Therefore, when a projection lens is formed of a material that transmits ultraviolet light such as KrF and ArF laser beams, chromatic aberration may occur. As a result, the resolution may decrease. Thus, the spectral linewidth of the laser beam output from the gas laser apparatus needs to be narrowed to an extent that the chromatic aberration is ignorable. Therefore, in a laser resonator of the gas laser apparatus, a line narrowing module (INMd) including a line narrowing element (such as etalon or grating) may be provided in order to narrow the spectral linewidth. Hereinafter, a gas laser apparatus with a narrowed spectral linewidth is referred to as a line narrowing gas laser apparatus.

### LIST OF DOCUMENTS

### Patent Documents

Patent Document 1: U.S. Pat. No. 6,810,061
Patent Document 2: U.S. Pat. No. 6,639,929
Patent Document 3: Japanese Unexamined Patent Application Publication No. 6-85350
Patent Document 4: Japanese Patent No. 4579002
Patent Document 5: Japanese Patent No. 4918699

### SUMMARY

A chamber device of a gas laser apparatus according to one aspect of the present disclosure may include a chamber body, an anode, a cathode, a cathode-side cover part, a cathode-side acoustic absorbing member, and an inclined part. The anode may be disposed in an internal space of the chamber body and longitudinally extend along a predetermined direction. The cathode may be disposed in the internal space in a first direction of facing and separating from the anode, longitudinally extend along the predetermined direction, and include a base part and a discharge part having a width smaller than a width of the base part in a second direction perpendicular to the predetermined direction and the first direction and protruding from the base part toward the anode. The cathode-side cover part may include a base facing part separated from the base part and overlapping a part of the base part in the first direction and separated from the discharge part and overlapping the discharge part in the second direction, and cover a part of the base part. The cathode-side acoustic absorbing member may be disposed in a space between the cathode-side cover part and the base part. The inclined part may include an inclined surface that is positioned at least partially in a space closer to the base part than the base facing part in the first direction and closer to the discharge part than the base facing part in the second direction, broadens to an opposite side with respect to the discharge part as the inclined surface is closer to the base part from the discharge part, and extends in the predetermined direction.

A gas laser apparatus according to one aspect of the present disclosure may be a gas laser apparatus including a chamber device configured to output a laser beam, and the chamber device may include a chamber body, an anode, a cathode, a cathode-side cover part, a cathode-side acoustic absorbing member, and an inclined part. The anode may be disposed in an internal space of the chamber body and longitudinally extend along a predetermined direction. The cathode may be disposed in the internal space in a first direction of facing and separating from the anode, longitudinally extend along the predetermined direction, and include a base part and a discharge part having a width smaller than a width of the base part in a second direction perpendicular to the predetermined direction and the first direction and protruding from the base part toward the anode. The cathode-side cover part may include a base facing part separated from the base part and overlapping a part of the base part in the first direction and separated from the discharge part and overlapping the discharge part in the second direction, and cover the base part. The cathode-side acoustic absorbing member may be disposed in a space between the cathode-side cover part and the base part. The inclined part may include an inclined surface that is disposed at least partially in a space closer to the base part than the base facing part in the first direction and closer to the discharge part than the base facing part in the second direction, broadens to an opposite side with respect to the discharge part as the inclined surface is closer to the base part from the discharge part, and extends in the predetermined direction.

An electronic device manufacturing method according to one aspect of the present disclosure may include generating a laser beam with a gas laser apparatus, outputting the laser beam to an exposure apparatus, and exposing a photosensitive substrate to the laser beam within the exposure apparatus to manufacture an electronic device. The gas laser apparatus may include a chamber device including a chamber body, an anode that is disposed in an internal space of the chamber body and longitudinally extends along a predetermined direction, a cathode that is disposed in the internal space in a first direction of facing and separating from the anode, longitudinally extends along the predetermined direction, and includes a base part and a discharge part having a width smaller than a width of the base part in a second direction perpendicular to the predetermined direction and the first direction and protruding from the base part toward the anode, a cathode-side cover part that includes a base facing part separated from the base part and overlapping a part of the base part in the first direction and separated from the discharge part and overlapping the discharge part in the second direction, and covers the base part, a cathode-side acoustic absorbing member disposed in a space between the cathode-side cover part and the base part, and an inclined part including an inclined surface that is disposed at least partially in a space closer to the base part than the base facing part in the first direction and closer to the discharge part than the base facing part in the second direction, broadens to an opposite side with respect to the discharge part as the inclined surface is closer to the base part from the discharge part, and extends in the predetermined direction.

### BRIEF DESCRIPTION OF THE DRAWINGS

Some embodiments of the present disclosure will be described below, by way of example only, with reference to the accompanying drawings.

FIG. 1 is a schematic diagram illustrating a schematic configuration example of an entire electronic device manufacturing apparatus.

FIG. 2 is a schematic diagram illustrating a schematic configuration example of an entire gas laser apparatus of a comparative example.

FIG. 3 is a sectional view perpendicular to an optical axis of a laser beam of a chamber device of the comparative example.

FIG. 4 is a sectional view perpendicular to the optical axis of the laser beam around a cathode and an anode illustrated in FIG. 3.

FIG. 5 is a sectional view perpendicular to the optical axis of the laser beam around the cathode illustrated in FIG. 3.

FIG. 6 is a sectional view perpendicular to the optical axis of the laser beam around a cathode in Embodiment 1.

FIG. 7 is a sectional view perpendicular to the optical axis of the laser beam around the cathode in Embodiment 1.

FIG. 8 is a sectional view perpendicular to the optical axis of the laser beam around the cathode in Embodiment 1.

FIG. 9 is a sectional view perpendicular to the optical axis of the laser beam around the cathode.

FIG. 10 is a perspective view of an inclined part in a first modification of Embodiment 1.

FIG. 11 is a sectional view perpendicular to the optical axis of the laser beam around a cathode in a second modification of Embodiment 1.

FIG. 12 is a sectional view perpendicular to the optical axis of the laser beam around a cathode in a third modification of Embodiment 1.

FIG. 13 is a sectional view perpendicular to the optical axis of the laser beam around a cathode in a fourth modification of Embodiment 1.

FIG. 14 is a sectional view perpendicular to the optical axis of the laser beam around a cathode in Embodiment 2.

FIG. 15 is a sectional view perpendicular to the optical axis of the laser beam around a cathode in Embodiment 3.

FIG. 16 is a sectional view taken along an A-A line indicated by arrows in FIG. 15.

FIG. 17 is a sectional view taken along a B-B line indicated by arrows in FIG. 16.

FIG. 18 is a sectional view viewed taken along a C-C line indicated by arrows in FIG. 16.

FIG. 19 is a sectional view taken along a D-D line indicated by arrows in FIG. 16.

FIG. 20 is a sectional view perpendicular to the optical axis of the laser beam around a cathode in Embodiment 4.

FIG. 21 is a sectional view perpendicular to the optical axis of the laser beam around a cathode in Embodiment 5.

FIG. 22 is a sectional view perpendicular to the optical axis of the laser beam around a cathode in Embodiment 6.

FIG. 23 is a sectional view perpendicular to the optical axis of the laser beam around an anode in Embodiment 7.

### DESCRIPTION OF EMBODIMENTS

1. Description of Electronic Device Manufacturing Apparatus Used in Electronic Device Exposure Process
2. Description of Comparative Example
   2.1 Configuration
   2.2 Operation
3. Problem
4. Description of Embodiment 1
   4.1 Configuration
   4.2 Effect
   4.3 First Modification of Embodiment 1
      4.3.1 Configuration
      4.3.2 Effect
   4.4 Second Modification of Embodiment 1
      4.4.1 Configuration
      4.4.2 Effect
   4.5 Third Modification of Embodiment 1
      4.5.1 Configuration
      4.5.2 Effect
   4.6 Fourth Modification of Embodiment 1
      4.6.1 Configuration
      4.6.2 Effect
5. Description of Embodiment 2
   5.1 Configuration
   5.2 Effect
6. Description of Embodiment 3
   6.1 Configuration
   6.2 Effect
7. Description of Embodiment 4
   7.1 Configuration
   7.2 Effect
8. Description of Embodiment 5
   8.1 Configuration
   8.2 Effect
9. Description of Embodiment 6
   9.1 Configuration
   9.2 Effect
10. Description of Embodiment 7
   10.1 Configuration
   10.2 Effect

Hereinafter, embodiments of the present disclosure will be described in detail with reference to the drawings. The embodiments described below show some examples of the present disclosure and do not limit contents of the present disclosure. In addition, all configurations and operations described in the embodiments are not necessarily essential as configurations and operations of the present disclosure. Here, the same components are denoted by the same reference signs, and any redundant description thereof is omitted.

### 1. DESCRIPTION OF ELECTRONIC DEVICE MANUFACTURING APPARATUS USED IN ELECTRONIC DEVICE EXPOSURE PROCESS

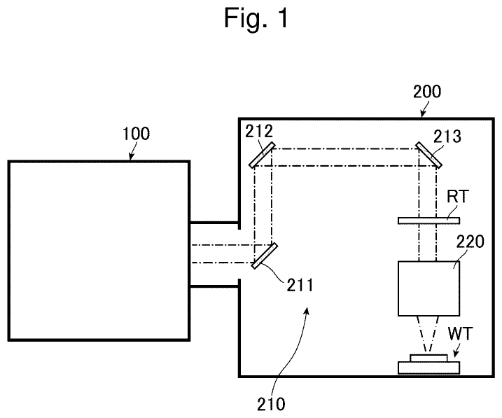

FIG. 1 is a schematic diagram illustrating a schematic configuration example of an entire electronic device manufacturing apparatus used in an electronic device exposure process. As illustrated in FIG. 1, the manufacturing apparatus used in the exposure process includes a gas laser apparatus 100 and an exposure apparatus 200. The exposure apparatus 200 includes an illumination optical system 210 including a plurality of mirrors 211, 212, and 213, and a projection optical system 220. The illumination optical system 210 illuminates a reticle pattern of a reticle stage RT with a laser beam entering from the gas laser apparatus 100. The projection optical system 220 performs reduced projection of a laser beam transmitted through a reticle, and forms an image on an unillustrated workpiece disposed on a workpiece table WT. The workpiece is a photosensitive substrate such as a semiconductor wafer on which photoresist is applied. The exposure apparatus 200 synchronously translates the reticle stage RT and the workpiece table WT to expose the workpiece to a laser beam reflecting the reticle pattern. By transferring a device pattern onto the semiconductor wafer by the exposure process as described above, a semiconductor device that is an electronic device can be manufactured.

### 2. DESCRIPTION OF COMPARATIVE EXAMPLE

### 2.1 Configuration

The gas laser apparatus 100 of the comparative example will be described. The comparative example of the present disclosure is an example recognized by the applicant as known only by the applicant, and is not a publicly known example admitted by the applicant.

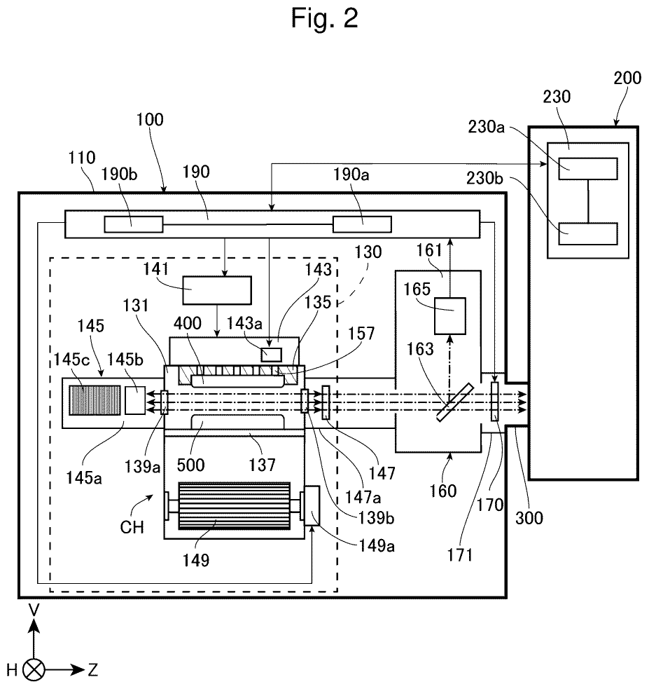

FIG. 2 is a schematic diagram illustrating a schematic configuration example of the entire gas laser apparatus 100 of the comparative example. The gas laser apparatus 100 is, for example, an ArF excimer laser apparatus using a mixed gas including argon (Ar), fluorine (F₂), and neon (Ne). The gas laser apparatus 100 outputs a laser beam having a center wavelength of about 193 nm. The gas laser apparatus 100 may be a gas laser apparatus other than an ArF excimer laser apparatus, and may be, for example, a KrF excimer laser apparatus using a mixed gas including krypton (Kr), F₂, and Ne. In this case, the gas laser apparatus 100 outputs a laser beam having a center wavelength of about 248 nm. The mixed gas containing Ar, F₂, and Ne as a laser medium and a mixed gas containing Kr, F₂, and Ne as a laser medium may be referred to as a laser gas.

The gas laser apparatus 100 mainly includes a housing 110, and a laser oscillator 130, a monitor module 160, a shutter 170, and a laser processor 190 that are disposed in an internal space of the housing 110.

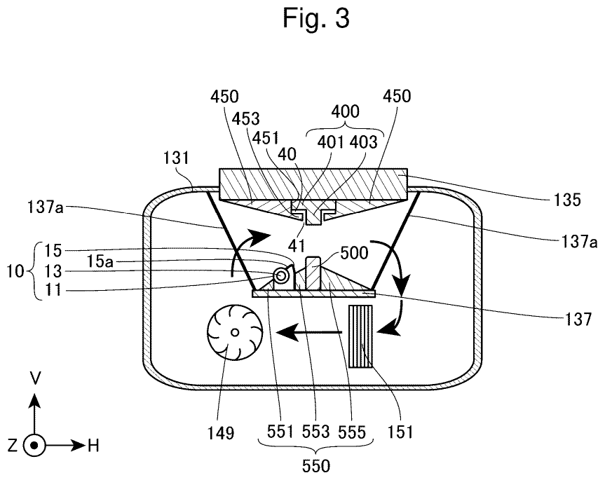

The laser oscillator 130 includes a chamber device CH, a charger 141, and an output coupling mirror 147. FIG. 2 illustrates an internal configuration of a chamber body 131 when viewed from a direction substantially perpendicular to a traveling direction of a laser beam. FIG. 3 is a sectional view perpendicular to an optical axis of the laser beam of the chamber body 131 of the comparative example.

The chamber device CH includes the chamber body 131, a cathode 400, an anode 500, cathode-side cover parts 450, and cathode-side acoustic absorbing members 470 to be described later. Examples of a material of the chamber body 131 include, for example, a metal such as aluminum plated with nickel or stainless steel plated with nickel. The chamber body 131 includes an internal space in which the laser gas is enclosed and light is generated by excitation of a laser medium in the laser gas. The light travels to windows 139a and 139b to be described later. The laser gas is supplied from an unillustrated laser gas supply source to the internal space of the chamber body 131 through an unillustrated pipe. Further, the laser gas in the chamber body 131 is subjected to processing of removing F₂ gas by a halogen filter or the like, and is exhausted to an outside of the housing 110 through an unillustrated pipe by an unillustrated exhaust pump.

In the internal space of the chamber body 131, the cathode 400 as a first main electrode and the anode 500 as a second main electrode are separated from each other and face each other, and their longitudinal directions are along a predetermined direction that is a traveling direction of the laser beam. Hereinafter, the longitudinal direction of the cathode 400 and the anode 500 may be described as a Z direction, and a direction in which the cathode 400 and the anode 500 are separated from each other and which is orthogonal to the Z direction may be described as a V direction or a first direction. In addition, a direction orthogonal to the V direction and the Z direction may be described as an H direction or a second direction. The cathode 400 and the anode 500 are discharge electrodes for exciting the laser medium by glow discharge.

The cathode 400 is fixed to the surface of a planar electrical insulating part 135 on the internal space side in the chamber body 131 by conductive members 157 each formed of, for example, a bolt. The conductive members 157 are electrically connected to a pulse power module 143 and apply a high voltage from the pulse power module 143 to the cathode 400. The anode 500 is supported by and is electrically connected to a ground plate 137.

The electrical insulating part 135 includes an insulator. Examples of a material of the electrical insulating part 135 include, for example, alumina ceramics having poor reactivity with F₂ gas. Note that the electrical insulating part 135 needs to be electrically insulating, and examples of the material of such an electrical insulating part 135 include a resin such as phenol resin or fluororesin, quartz, and glass. The electrical insulating part 135 closes an opening provided in the chamber body 131, and is fixed to the chamber body 131.

The charger 141 is a DC power supply device that charges an unillustrated charging capacitor in the pulse power module 143 with a predetermined voltage. The pulse power module 143 includes a switch 143a controlled by the laser processor 190. When the switch 143a is turned ON from OFF, the pulse power module 143 generates a pulsed high voltage from electric energy charged in the charging capacitor and applies this high voltage to the cathode 400.

When the high voltage is applied to the cathode 400, discharge occurs between the cathode 400 and the anode 500. Energy of the discharge excites a laser medium in a discharge space between the cathode 400 and the anode 500 (hereinafter, simply referred to as the discharge space), and the excited laser medium outputs light when shifting to a ground state.

The paired windows 139a and 139b are provided on the wall of the chamber body 131. The window 139a is located on one side in the traveling direction of the laser beam in the chamber body 131 whereas the window 139b is located on the other side in the traveling direction, and the windows 139a and 139b sandwich the discharge space. The windows 139a and 139b are inclined to form a Brewster's angle with respect to the traveling direction of the laser beam so as to suppress reflection of P-polarized light of the laser beam. The laser beam oscillated as to be described later is output to the outside of the chamber body 131 through the windows 139a and 139b. Since the pulsed high voltage is applied between the cathode 400 and the anode 500 by the pulse power module 143 as described above, the laser beam is a pulse laser beam.

A cross flow fan 149 and a heat exchanger 151 are further disposed in the internal space of the chamber body 131.

The cross flow fan 149 and the heat exchanger 151 are disposed on the side opposite to the anode 500 with respect to the ground plate 137. In the internal space of the chamber body 131, a space in which the cross flow fan 149 and the heat exchanger 151 are disposed communicates with the discharge space. The heat exchanger 151 is a radiator disposed beside the cross flow fan 149 and connected to an unillustrated pipe through which a liquid or gas cooling medium flows. As illustrated in FIG. 2, the cross flow fan 149 is connected to a motor 149a disposed outside the chamber body 131, and is rotated by rotation of the motor 149a. As the cross flow fan 149 is rotated, the laser gas enclosed in the internal space of the chamber body 131 is circulated as illustrated by bold arrows in FIG. 3. That is, the laser gas is circulated through the cross flow fan 149, the discharge space, the heat exchanger 151, and the cross flow fan 149 in the order. Accordingly, at least a part of the circulated laser gas passes through the heat exchanger 151, and a temperature of the laser gas is adjusted by the heat exchanger 151. By circulation of the laser gas, impurities of the laser gas generated by main discharge between the cathode 400 and the anode 500 are moved to a downstream side, and a fresh laser gas is supplied to the discharge space at the time of next discharge. Further, when the laser gas passes through the heat exchanger 151, heat associated with the main discharge is removed, and an increase in temperature of the laser gas is suppressed. The ON/OFF switching and the rotational number of the motor 149a are adjusted by control of the laser processor 190. Accordingly, the laser processor 190 can adjust the circulation speed of the laser gas circulated in the internal space of the chamber body 131 by controlling the motor 149a.

Note that the laser gas flows in a +H direction between the cathode 400 and the anode 500, a −H direction side may be described as an upstream side, and a +H direction side may be described as a downstream side.

The ground plate 137 is electrically connected to the chamber body 131 via wires 137a. The anode 500 supported by the ground plate 137 is connected to a ground potential via the ground plate 137, the wires 137a, and the chamber body 131.

On the ground plate 137, an anode-side cover part 550 covering the sides of the anode 500 is disposed. The anode-side cover part 550 includes cover members 551, 553, and 555, and the cover members 551, 553, and 555 are arranged in this order from upstream to downstream of the flow of the laser gas. The cover member 551 is fixed to the ground plate 137 with unillustrated bolts, a preionization electrode 10 is provided between the cover member 551 and the cover member 553, the cover member 553 and the cover member 555 sandwich the anode 500. The anode 500 is fixed onto the ground plate 137 with unillustrated bolts, and the cover member 553 and the cover member 555 are fixed to the anode 500 with unillustrated bolts. Examples of a material of the respective cover members 551, 553, and 555 include, for example, a porous nickel metal having low reactivity with F₂ gas. The cover members 551, 553, and 555 guide the laser gas such that the laser gas is made to flow from the cross flow fan 149 to the heat exchanger 151 through the discharge space by ventilation of the cross flow fan 149.

The preionization electrode 10 is provided on the side of the anode 500 in the H direction on the ground plate 137. In the present example, the preionization electrode 10 is provided upstream of the anode 500. The preionization electrode 10 includes a dielectric pipe 11, a preionization inner electrode, and a preionization outer electrode. Hereinafter, the preionization inner electrode and the preionization outer electrode may be referred to as an inner electrode 13 and an outer electrode 15, respectively.

The dielectric pipe 11 is, for example, a cylindrical member, and extends along the Z direction. Examples of a material of the dielectric pipe 11 include alumina ceramics and sapphire.

The inner electrode 13 has a rod shape, is disposed inside the dielectric pipe 11, and extends along a longitudinal direction of the dielectric pipe 11. Examples of a material of the inner electrode 13 include copper and brass.

The outer electrode 15 is disposed between the dielectric pipe 11 and the cover member 553, and extends along the longitudinal direction of the dielectric pipe 11. The outer electrode 15 includes an end portion 15a facing a part of an outer peripheral surface of the dielectric pipe 11. The end portion 15a is provided from one end to the other end of the outer electrode 15 in the longitudinal direction of the outer electrode 15. The outer electrode 15 is bent in an in-plane direction perpendicular to the longitudinal direction of the dielectric pipe 11, and the end portion 15a is in contact with an outer peripheral surface of the dielectric pipe 11 so as to push the outer peripheral surface of the dielectric pipe 11 by bending. A part of the outer peripheral surface of the dielectric pipe 11 that is substantially opposite to a contact part where the end portion 15a of the outer electrode 15 is in contact is in contact with the cover member 551. Therefore, even when the outer electrode 15 presses the dielectric pipe 11, the dielectric pipe 11 is supported by the cover member 551. An unillustrated screw hole is provided on an end portion of the outer electrode 15 opposite to the end portion 15a, and the outer electrode 15 is fixed to the cover member 553 with an unillustrated screw screwed into the screw hole. Therefore, it can be understood that the outer electrode 15 is fixed to the anode 500 via the cover member 553. Examples of a material of the outer electrode 15 include copper and brass.

The paired cathode-side cover parts 450 are disposed on the surface of the electrical insulating part 135 on the internal space side in the chamber body 131. The cathode-side cover parts 450 are individually disposed on the upstream side and the downstream side of the cathode 400, extend in the Z direction along the cathode 400, and are separate from each other. Each cathode-side cover part 450 is fixed to the electrical insulating part 135 with unillustrated bolts. A cross-sectional shape of the cathode-side cover part 450 is generally a right-angled triangle, and the cathode-side cover part 450 gradually increases in height in the V direction as it is closer to the cathode 400 in the H direction. Such cathode-side cover parts 450 guide the laser gas in the same manner as the anode-side cover part 550.

A line narrowing module 145 illustrated in FIG. 2 includes a housing 145a, and a prism 145b, a grating 145c, and an unillustrated rotation stage that are disposed in an internal space of the housing 145a. An opening is formed in the housing 145a, and the housing 145a is connected to a rear side of the chamber body 131 via the opening.

The prism 145b widens a beam width of light output from the window 139a and makes the light enter the grating 145c. Further, the prism 145b reduces a beam width of reflected light from the grating 145c and returns the light to the internal space of the chamber body 131 through the window 139a. The prism 145b is supported by the rotation stage and is rotated by the rotation stage. By rotation of the prism 145b, an incident angle of the light to the grating 145c is changed. Accordingly, the rotation of the prism 145b makes it possible to select a wavelength of the light returning from the grating 145c to the chamber body 131 through the prism 145b. While FIG. 2 illustrates an example in which one prism 145b is disposed, at least one prism may be disposed.

A surface of the grating 145c is formed of a material having a high reflectance, and many grooves are provided on the surface at predetermined intervals. A cross-sectional shape of each groove is, for example, a right-angled triangle. The light entering the grating 145c from the prism 145b is diffracted in a direction corresponding to the wavelength of the light when reflected by the grooves. The grating 145c is disposed in Littrow arrangement such that the incident angle of the light entering the grating 145c from the prism 145b coincides with a diffracting angle of diffracted light having a desired wavelength. Thus, the light near the desired wavelength is returned to the chamber body 131 through the prism 145b.

The output coupling mirror 147 is disposed in an internal space of an optical path pipe 147a connected to a front side of the chamber body 131, and faces the window 139b. The output coupling mirror 147 transmits a part of the laser beam output from the window 139b toward the monitor module 160, reflects the other part back into the internal space of the chamber body 131 through the window 139b. Thus, the grating 145c and the output coupling mirror 147 form a Fabry-Perot laser resonator, and the chamber body 131 is disposed on an optical path of the laser resonator.

The monitor module 160 is disposed on an optical path of the laser beam output from the output coupling mirror 147. The monitor module 160 includes a housing 161, and a beam splitter 163 and a photosensor 165 disposed in an internal space of the housing 161. An opening is formed in the housing 161, and the internal space of the housing 161 communicates with the internal space of the optical path pipe 147a through the opening.

The beam splitter 163 transmits a part of the laser beam output from the output coupling mirror 147 toward the shutter 170, and reflects the other part of the laser beam toward a light receiving surface of the photosensor 165. The photosensor 165 measures energy E of the laser beam incident on the light receiving surface, and outputs a signal indicating the measured energy E to the laser processor 190.

The laser processor 190 of the present disclosure is a processing device including a storage device 190a in which a control program is stored, and a CPU (Central Processing Unit) 190b which executes the control program. The laser processor 190 is specifically configured or programmed to execute various kinds of processing included in the present disclosure. The laser processor 190 controls the entire gas laser apparatus 100.

The laser processor 190 transmits and receives various kinds of signals to and from an exposure processor 230 of the exposure apparatus 200. For example, the laser processor 190 receives, from the exposure processor 230, signals indicating a light emission trigger Tr to be described later and target energy Et or the like. The target energy Et has a target value for the energy of the laser beam used in the exposure process. The laser processor 190 controls a charging voltage of the charger 141 based on the energy E and the target energy Et received from the photosensor 165 and the exposure processor 230. By controlling the charging voltage, the energy of the laser beam is controlled. In addition, the laser processor 190 transmits a command signal for ON or OFF of the switch 143a to the pulse power module 143. Further, the laser processor 190 is electrically connected to the shutter 170 and controls opening and closing of the shutter 170.

The laser processor 190 closes the shutter 170 until a difference ΔE between the energy E received from the monitor module 160 and the target energy Et received from the exposure processor 230 falls within an allowable range. When the difference ΔE falls within the allowable range, the laser processor 190 transmits a reception ready signal which reports that the light emission trigger Tr is ready to be received to the exposure processor 230. The exposure processor 230 transmits the signal indicating the light emission trigger Tr to the laser processor 190 upon receiving the reception ready signal, and the laser processor 190 opens the shutter 170 upon receiving the signal indicating the light emission trigger Tr. The light emission trigger Tr is defined by a predetermined repetition frequency f of the laser beam and a predetermined number P of pulses, is a timing signal for causing the exposure processor 230 to laser-oscillate the laser oscillator 130, and is an external trigger. The repetition frequency f of the laser beam is, for example, equal to or higher than 100 Hz and equal to or lower than 10 kHz.

The shutter 170 is disposed in an optical path of the laser beam in an internal space of an optical path pipe 171 communicating with an opening formed on the side opposite to the side where the optical path pipe 147a is connected in the housing 161 of the monitor module 160. The internal spaces of the optical path pipes 171 and 147a and the internal spaces of the housings 161 and 145a are supplied and filled with a purge gas. The purge gas includes an inert gas such as nitrogen (N₂). The purge gas is supplied from an unillustrated purge gas supply source through an unillustrated pipe. The optical path pipe 171 communicates with the exposure apparatus 200 through an opening of the housing 110 and an optical path pipe 300 connecting the housing 110 and the exposure apparatus 200. The laser beam that has passed through the shutter 170 enters the exposure apparatus 200.

The exposure processor 230 of the present disclosure is a processing device including a storage device 230a in which a control program is stored, and a CPU 230b which executes the control program. The exposure processor 230 is specifically configured or programmed to execute various kinds of processing included in the present disclosure. The exposure processor 230 controls the entire exposure apparatus 200.

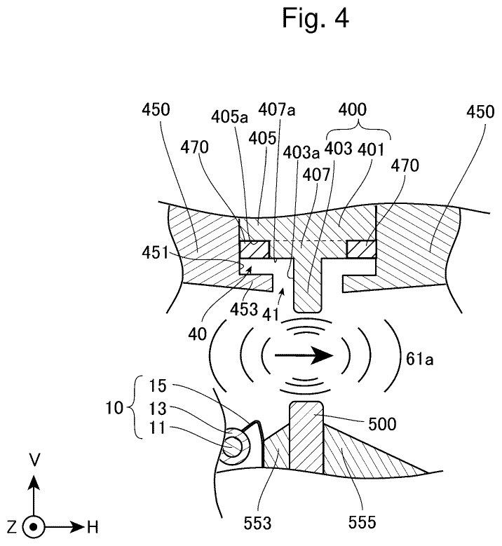

FIG. 4 is a sectional view perpendicular to the optical axis of the laser beam around the cathode 400 and the anode 500 illustrated in FIG. 3. In FIG. 4, the laser gas flowing through the discharge space is indicated by a bold arrow. The cathode 400 includes a base part 401 and a discharge part 403 protruding from the base part 401 toward the anode 500. The base part 401 of the cathode 400 is fixed to the electrical insulating part 135 by the conductive members 157. The base part 401 and the discharge part 403 longitudinally extend along the Z direction, and have a same length as the cathode 400 in the Z direction. The base part 401 is wider in the H direction than the discharge part 403, and a surface 407a of the base part 401 is positioned on both sides of the discharge part 403 in the H direction. In FIG. 4, for the sake of clarity, a sign is attached only to one surface 407a. A side face of the base part 401 along a VZ plane is in contact with a part of a side face 451 of the cathode-side cover part 450. The other part of the side face 451 is not in contact with the cathode 400, and a space is provided between the other part of the side face 451 and a side face 403a along the VZ plane of the discharge part 403. Further, the discharge part 403 extends closer to the anode 500 than base facing parts 453 to be described later of the cathode-side cover parts 450. Therefore, an end portion of the discharge part 403 on the anode 500 side is located closer to the anode 500 than the cathode-side cover parts 450. Note that illustration of the cathode 400 is simplified in FIG. 2.

The base facing part 453 of each cathode-side cover part 450 is connected to a part of the side face 451 of the cathode-side cover part 450, and extends in the H direction toward the side face of the discharge part 403. Each base facing part 453 is separated from the base part 401 and overlaps a part of the base part 401 in the V direction, and is separated from the discharge part 403 and overlaps a part of the discharge part 403 in the H direction. In addition, each base facing part 453 extends in the Z direction and has substantially the same length as the cathode 400 in the Z direction. Such a base facing part 453 covers a part of the base part 401, and a gap 40 is provided between the base facing part 453 and the surface 407a of the base part 401. The gap 40 is a generally L-shaped space surrounded by an entrance 41 of the gap 40 provided between the side face of the discharge part 403 and the base facing part 453, the base facing part 453, the side face 451, the surface 407a, and the side face of the discharge part 403. Such a gap 40 can suppress assembly of the cathode 400 and the cathode-side cover part 450 from becoming impossible due to interference caused by dimensional errors in manufacturing of the cathode 400 and the cathode-side cover part 450. The cathode-side cover part 450 defining the gap 40 covers a part of the cathode 400 from the side.

The cathode-side cover part 450 is provided on each of the upstream side and the downstream side of the flow of the laser gas in the cathode 400. Therefore, the gap 40 is separately provided on each of the upstream side and the downstream side of the flow of the laser gas with respect to the cathode 400. In FIG. 3 and FIG. 4, for the sake of clarity, signs are attached only to the gap 40 and the entrance 41 on one side. Acoustic waves 61a illustrated in FIG. 4 will be described later.

The chamber body 131 of the present comparative example includes the cathode-side acoustic absorbing member 470 in each gap 40 on the upstream side and on the downstream side of the flow of the laser gas in the cathode 400. The cathode-side acoustic absorbing member 470 is formed of, for example, a porous member. Examples of a material of the cathode-side acoustic absorbing member 470 include, for example, metals such as nickel, copper, iron, stainless steel, and brass. The cathode-side acoustic absorbing member 470 may be an electrical insulator as long as it is formed of a porous member, and examples of the material of such a cathode-side acoustic absorbing member 470 include, for example, alumina ceramics.

As illustrated in FIG. 4, the base part 401 of the present comparative example includes a first base part 405 and a second base part 407. A broken line in FIG. 4 is a boundary line that virtually separates the first base part 405 and the second base part 407. Hereinafter, the description of this boundary line will be omitted. The second base part 407 is provided on the first base part 405 on the opposite side to the electrical insulating part 135. The second base part 407 protrudes from the first base part 405 toward the anode 500. The first base part 405 is wider in the H direction than the second base part 407, and surfaces 405a of the first base part 405 are provided at respective positions sandwiching the second base part 407 in the H direction. The discharge part 403 is provided on the second base part 407 on the opposite side to the first base part 405. The discharge part 403 protrudes from the second base part 407 toward the anode 500. The second base part 407 is wider in the H direction than the discharge part 403, and the surfaces 407a of the second base part 407 are provided at respective positions sandwiching the discharge part 403 in the H direction. Each surface 407a faces the entrance 41, and when the cathode 400 is viewed along the V direction, each surface 407a is exposed through the entrance 41. In FIG. 4, for the sake of clarity, signs are attached only to the surfaces 405a and 407a on one side. The first base part 405 is in contact with a part of the side face 451 of each cathode-side cover part 450, and the second base part 407 is not in contact with the side face 451. That is, the cathode-side cover parts 450 are separated from the second base part 407, which is a part of the base part 401. The first base part 405 and the second base part 407 are disposed closer to the electrical insulating part 135 than the entrance 41.

The cathode-side acoustic absorbing members 470 of the present comparative example are disposed on the base part 401. Specifically, each cathode-side acoustic absorbing member 470 is disposed on the surface 405a of the first base part 405 and is screwed to the first base part 405. Each cathode-side acoustic absorbing member 470 is provided in the gap 40 between the second base part 407 which is a part of the base part 401 and the side face 451 of the cathode-side cover part 450, is in contact with the side face of the second base part 407, and faces the base facing part 453 and a part of the entrance 41 of the gap 40.

### 2.2 Operation

Next, an operation of the gas laser apparatus 100 of the comparative example will be described.

Before the gas laser apparatus 100 outputs the laser beam, the internal spaces of the optical path pipes 147a, 171, and 300 and the internal spaces of the housings 145a and 161 are filled with the purge gas from an unillustrated purge gas supply source. Further, the laser gas is supplied to the internal space of the chamber body 131 from an unillustrated laser gas supply source. When the laser gas is supplied, the laser processor 190 controls the motor 149a to rotate the cross flow fan 149. By the rotation of the cross flow fan 149, the laser gas is circulated in the internal space of the chamber body 131. At the time, the laser gas is guided from the cross flow fan 149 toward the discharge space by the cathode-side cover part 450 and the cover members 551 and 553 on the upstream side. Further, the laser gas is guided from the discharge space toward the heat exchanger 151 by the cathode-side cover part 450 and the cover member 555 on the downstream side.

When the gas laser apparatus 100 outputs the laser beam, the laser processor 190 receives a signal indicating the target energy Et and a signal indicating the light emission trigger Tr from the exposure processor 230. The laser processor 190 also turns ON the switch 143a of the pulse power module 143. Accordingly, the pulse power module 143 applies a pulsed high voltage between the cathode 400 and the anode 500 and between the inner electrode 13 and the outer electrode 15 from the electric energy charged in the unillustrated charging capacitor. When the high voltage is applied between the inner electrode 13 and the outer electrode 15, corona discharge occurs in the vicinity of the dielectric pipe 11 and the end portion 15a, and ultraviolet light is output. When the laser gas between the cathode 400 and the anode 500 is irradiated with the ultraviolet light, the laser gas between the cathode 400 and the anode 500 is preionized. After preionization, when the voltage between the cathode 400 and the anode 500 reaches a breakdown voltage, main discharge between the cathode 400 and the anode 500 occurs. Accordingly, excimers are generated from the laser medium contained in the laser gas between the cathode 400 and the anode 500, and light is output when the excimers are dissociated. The light goes back and forth between the grating 145c and the output coupling mirror 147 and is amplified every time it passes through the discharge space in the internal space of the chamber body 131, causing laser oscillation. A part of the laser beam is transmitted through the output coupling mirror 147 as a pulse laser beam and travels to the beam splitter 163.

A part of the laser beam that has traveled to the beam splitter 163 is reflected by the beam splitter 163 and is received by the photosensor 165. The photosensor 165 measures the energy E of the received laser beam, and outputs a signal indicating the energy E to the laser processor 190. The laser processor 190 controls the charging voltage such that the difference ΔE between the energy E and the target energy Et falls within an allowable range. Further, the other part of the laser beam that has traveled to the beam splitter 163 is transmitted through the beam splitter 163, passes through the shutter 170, and travels to the exposure apparatus 200.

In the gas laser apparatus 100, a high-temperature and high-pressure state is generated in the discharge space in an extremely short time by the main discharge between the cathode 400 and the anode 500. Thus, the acoustic waves 61a indicated by solid curves in a pseudo manner in FIG. 4 are generated in the discharge space. The acoustic waves 61a are compressional waves of the laser gas in the chamber body 131 and are propagated in the chamber body 131 while spreading from the discharge space. A propagation speed is generally 500 m/s.

A region where the acoustic waves 61a are propagated in the gap 40 of the present comparative example is a space surrounded by the entrance 41, the base facing part 453, the side face 451, the surface 405a, the surface 407a of the second base part 407 on the base facing part 453 side, and the side face of the discharge part 403. Such a gap 40 includes the entrance 41, a first space that is connected to the entrance 41 and has a rectangular cross section in the Z direction, and a second space that is connected to the first space, is positioned deeper than the first space, and has a rectangular cross section extending in the H direction. The cathode-side acoustic absorbing member 470 extends along the Z direction and has generally the same length as the cathode 400, but may be shorter than the cathode 400. The cathode-side acoustic absorbing member 470 is in contact with the second base part 407 and the side face 451, and is disposed in the gap 40 so as to be separated from the base facing part 453. The cathode-side acoustic absorbing member 470 absorbs the acoustic waves 61a propagated in the gap 40. The absorbed acoustic waves 61a are propagated while being repeatedly reflected inside the cathode-side acoustic absorbing member 470, are converted into thermal energy or the like, and are gradually attenuated. In addition, the acoustic waves 61a that have passed through the cathode-side acoustic absorbing member 470 are reflected by the base part 401 and the cathode-side cover part 450 around the cathode-side acoustic absorbing member 470, and are absorbed again by the cathode-side acoustic absorbing member 470. The absorbed acoustic waves 61a are repeatedly reflected inside the cathode-side acoustic absorbing member 470 as described above and are further attenuated.

### 3. PROBLEM

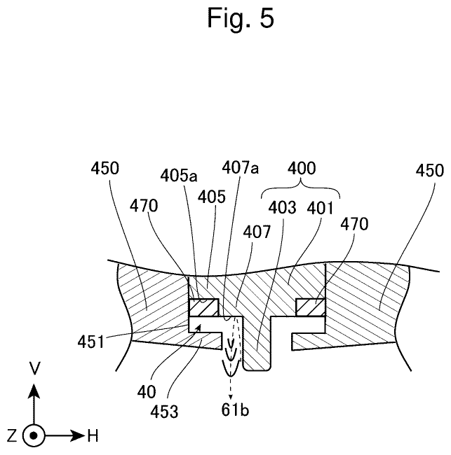

FIG. 5 is a sectional view perpendicular to the optical axis of the laser beam around the cathode 400. The acoustic waves 61a propagated from the entrance 41 to the gap 40 may be reflected by the surface 407a of the second base part 407 as illustrated in FIG. 5, and may return to the discharge space as reflected waves 61b.

When the reflected waves 61b are propagated to the discharge space at a timing at which the main discharge occurs, the reflected waves 61b change a density distribution of the laser gas in the discharge space, the main discharge becomes unstable, and stability of the energy of the laser beam output from the gas laser apparatus 100 may decline. In this manner, the reflected waves 61b may affect performance of the laser beam. In an operating environment in which the repetition frequency f of the laser beam is, for example, equal to or higher than 8.5 kHz, since discharge is made to occur at a timing at which the reflected waves 61b are not sufficiently attenuated, there is a possibility that the main discharge becomes unstable.

Therefore, the following embodiments exemplify the chamber device CH of the gas laser apparatus 100 capable of outputting a laser beam having stable pulse energy even at a high repetition frequency.

### 4. DESCRIPTION OF EMBODIMENT 1

Next, the chamber device CH of Embodiment 1 will be described. Any component same as that described above is denoted by the same sign, and any redundant description thereof is omitted unless specific description is needed. Further, in some drawings, a part of members may be omitted or simplified for clarity, and a reference sign is given only to a part of the same components, and the reference sign is omitted in some cases.

### 4.1 Configuration

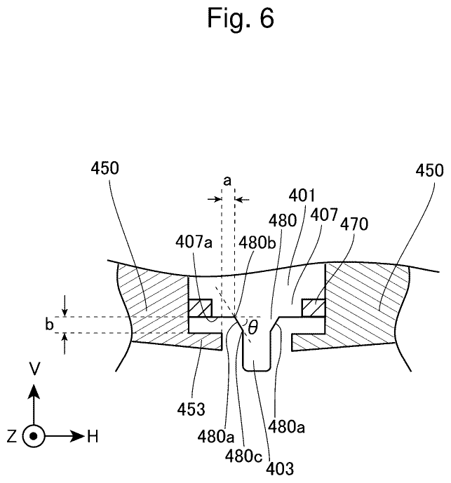

FIG. 6 is a sectional view perpendicular to the optical axis of the laser beam around the cathode 400 in the present embodiment. The chamber device CH of the present embodiment differs from the chamber device CH of the comparative example in that it includes an inclined part 480. In FIG. 6 to FIG. 22, hatching of the base part 401 is omitted.

In the present embodiment, the inclined part 480 is disposed on both sides of the discharge part 403 in the H direction. A longitudinal direction of the inclined part 480 extends along the Z direction. In the present embodiment, the inclined part 480 is formed integrally with the base part 401 and the discharge part 403. That is, the inclined part 480 is made of the same material as the base part 401 and the discharge part 403, and no joint is formed between the inclined part 480 and the base part 401 and between the inclined part 480 and the discharge part 403.

The inclined part 480 includes inclined surfaces 480a. Each inclined surface 480a is disposed at least partially in a space closer to the base part 401 than the base facing part 453 in the V direction and closer to the discharge part 403 than the base facing part 453 in the H direction. Each inclined surface 480a broadens to the opposite side with respect to the discharge part 403 as it is closer to the base part 401 from the discharge part 403 along the V direction.

In the present embodiment, the base facing part 453 and a base-side end portion 480b on the inclined surface 480a do not overlap each other in the V direction. When a distance in the H direction between the base-side end portion 480b, which is a position farthest from the discharge part 403 on the inclined surface 480a between the discharge part 403 and the base facing part 453 when the inclined surface 480a is viewed from the anode 500 along the V direction, and the base facing part 453 is defined as a, and a distance in the V direction between the base facing part 453 and the surface 407a of the second base part 407 facing the base facing part 453 is defined as b, an acute angle θ formed between the inclined surface 480a and the surface 407a of the second base part 407 facing the base facing part 453 satisfies Expression (1) below.

$$\frac{1}{2} {tan}^{- 1} ( \frac{a}{b} ) < θ < 90 ° - \frac{1}{2} {tan}^{- 1} ( \frac{a}{b} ) \qquad ( 1 )$$

Further, in the base part 401, it is desirable that a distance in the V direction between the surface 407a facing the base facing part 453 and a position 480c closest to the anode 500 on the inclined surface 480a be equal to or shorter than b.

### 4.2 Effect

In the chamber body 131 of the present embodiment, since the acoustic waves 61a reflected by the inclined surface 480a can be reflected to the surface of the base facing part 453 on the base part 401 side, the acoustic waves 61a can be guided to the gap 40 formed by the cathode-side cover part 450 and the base part 401, and the acoustic waves 61a can be absorbed by the cathode-side acoustic absorbing member 470 disposed in the gap 40. Therefore, the reflected waves 61b returning to the discharge space can be reduced, and the chamber body 131 of the gas laser apparatus 100 capable of outputting the laser beam having the stable pulse energy even at the high repetition frequency can be realized.

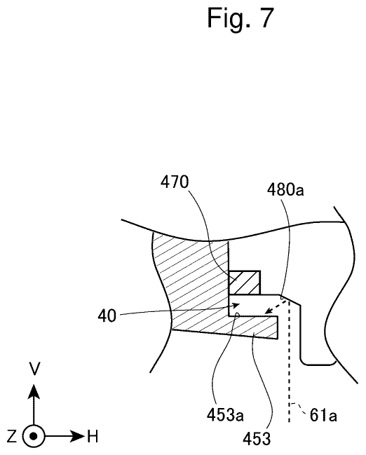

FIG. 7 is a diagram illustrating an example in which the acoustic waves 61a are reflected by the inclined surface 480a and are guided to the gap 40. After being reflected by the inclined surface 480a, the acoustic waves 61a are reflected by the surface 453a of the base facing part 453 on the base part 401 side, and are guided to a deep part of the gap 40. Consequently, the acoustic waves 61a easily reach the cathode-side acoustic absorbing member 470.

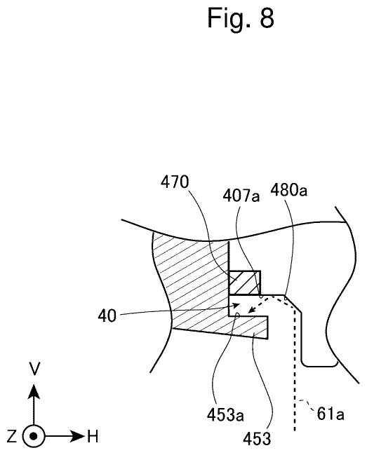

FIG. 8 is a diagram illustrating another example in which the acoustic waves 61a are reflected by the inclined surface 480a and are guided to the gap 40. The acoustic waves 61a are reflected by the inclined surface 480a and then reflected by the surface 407a of the base part 401 before the acoustic waves 61a are reflected by the surface 453a of the base facing part 453 on the base part 401 side and are guided to the deep part of the gap 40. Consequently, the acoustic waves 61a easily reach the cathode-side acoustic absorbing member 470.

In addition, in the chamber body 131 of the present embodiment, since it is possible to avoid a reduction in the distance between the inclined surface 480a and the base facing part 453, the acoustic waves 61a can be easily guided into the gap 40.

In the chamber body 131 of the present embodiment, since the inclined part 480 is integrated with at least one of the discharge part 403 and the base part 401, a fastening element for fixing the inclined part 480 is not required. Therefore, the inclined surface 480a hardly becomes uneven. Therefore, the acoustic waves 61a can be easily reflected by the inclined surface 480a to reach the gap 40, can easily reach the cathode-side acoustic absorbing member 470 disposed in the gap 40, and can be easily absorbed.

While the inclined part 480 is disposed symmetrically on both sides in the H direction of the discharge part 403 in the chamber body 131 of the present embodiment, the present invention is not limited thereto. That is, the inclined part 480 may be provided only on the −H direction side with respect to the discharge part 403, and the inclined part 480 may be provided only on the +H direction side with respect to the discharge part 403. The inclined part 480 on the +H direction side and the inclined part 480 on the −H direction side may have different shapes.

While a case where the angle θ satisfies Expression (1) is illustrated for the inclined part 480, the present invention is not limited thereto. At least a part of the inclined surface 480a may be disposed in a space closer to the base part 401 than the base facing part 453 in the V direction and closer to the discharge part 403 than the base facing part 453 in the H direction.

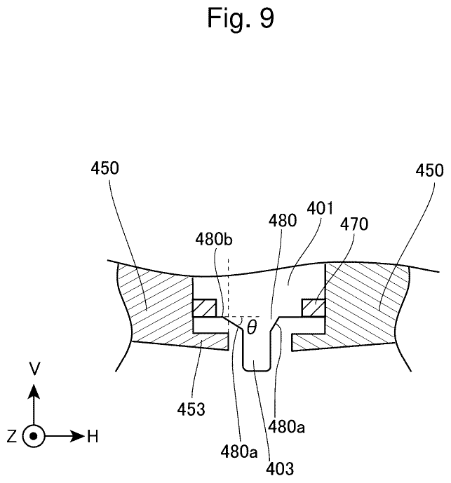

Further, while the present embodiment illustrates an example in which the cathode-side cover part 450 and the base-side end portion 480b on the inclined surface 480a do not overlap each other in the V direction, the present invention is not limited thereto. For example, as illustrated in FIG. 9, the cathode-side cover part 450 and the base-side end portion 480b on the inclined surface 480a may overlap each other in the V direction. In this case, a in Expression (1) is 0, and Expression (1) is modified as follows: 0°<θ<90°.

### 4.3 First Modification of Embodiment 1

### 4.3.1 Configuration

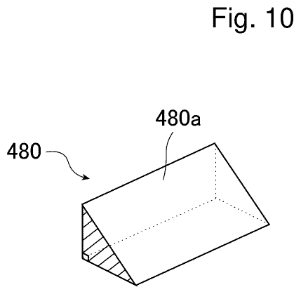

FIG. 10 is a perspective view of the inclined part 480 in a first modification. The present modification differs from the chamber body 131 of Embodiment 1 in that the inclined part 480 is separate from the cathode 400. In the present modification, the inclined part 480 is a triangular prism with a VH cross section in a shape of a right-angled triangle. In addition, the inclined part 480 may be fixed to the chamber body 131 with unillustrated bolts.

### 4.3.2 Effect

The inclined part 480 may be disposed in a retrofitting manner in the existing gas laser apparatus 100. In addition, when a discharge product is deposited on the inclined surface 480a, the inclined part 480 can be replaced with another inclined part 480 which is clean and has less ruggedness. Therefore, irregular reflection of the acoustic waves 61a due to the discharge product deposited on the surface of the inclined part 480 is suppressed, and a state where the acoustic waves 61a are effectively absorbed can be easily restored at a low cost.

Note that the inclined part 480 may be provided with inclined surfaces in different shapes between the −H direction side and the +H direction side of the discharge part 403 in accordance with intensity and a spatial distribution of the acoustic waves 61a entering the entrance 41 of the gap 40.

Further, while a triangular prism with a VH cross section in a shape of a right-angled triangle is exemplified as the inclined part 480 in the present modification, the present invention is not limited thereto. For example, the shape may be a right-angled isosceles triangle, a trapezoid, or a quadrangle.

### 4.4 Second Modification of Embodiment 1

### 4.4.1 Configuration

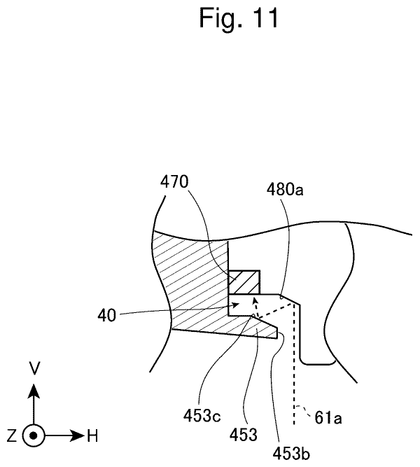

FIG. 11 is a diagram illustrating the base facing part 453 according to a second modification. An edge, on the base part 401 side, of the base facing part 453 of the present modification is chamfered, which differs from the chamber body 131 of Embodiment 1.

### 4.4.2 Effect

The acoustic waves 61a reflected by the inclined surface 480a are easily reflected not by an end face 453b of the base facing part 453 but by a surface 453c formed by chamfering. Therefore, the acoustic waves 61a easily reach the gap 40 and easily reach the cathode-side acoustic absorbing member 470 disposed in the gap 40, so that the acoustic waves 61a can be easily absorbed.

### 4.5 Third Modification of Embodiment 1

### 4.5.1 Configuration

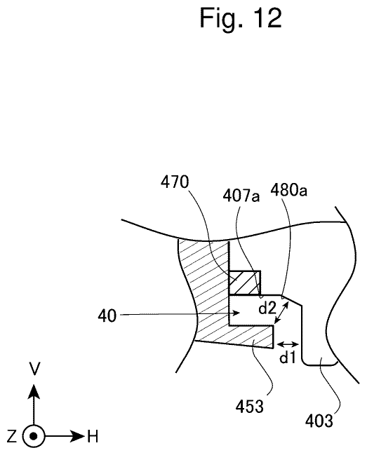

FIG. 12 is a sectional view perpendicular to the optical axis of the laser beam around the cathode 400 according to a third modification. The present modification differs from the chamber body 131 of Embodiment 1 in that a distance d2 between the base facing part 453 and the inclined surface 480a is equal to or longer than a distance d1 between the base facing part 453 and the discharge part 403. It is preferable that d1 be longer than 0.4 mm and be shorter than 5 mm.

### 4.5.2 Effect

Since the distance between the inclined surface 480a and the base facing part 453 can be increased, the acoustic waves 61a can be easily guided into the gap 40.

### 4.6 Fourth Modification of Embodiment 1

### 4.6.1 Configuration

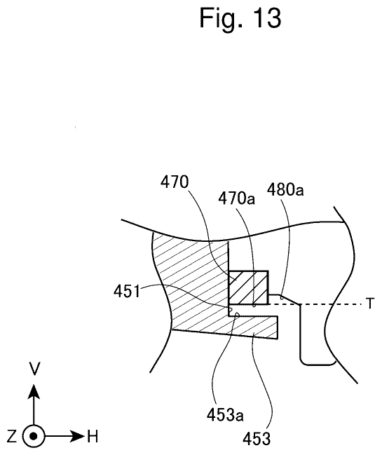

FIG. 13 is a sectional view perpendicular to the optical axis of the laser beam around the cathode 400 according to a fourth modification of Embodiment 1. The present modification differs from the chamber body 131 of Embodiment 1 in that the cathode-side acoustic absorbing member 470 is thick in the V direction and a distance in the V direction between the surface 453a of the base facing part 453 and a virtual plane T including a surface 470a of the cathode-side acoustic absorbing member 470 facing the base facing part 453, which is indicated by a broken line, is short.

### 4.6.2 Effect

Since the distance between the cathode-side acoustic absorbing member 470 disposed in the base part 401 and the base facing part 453 is reduced, the area of the side face 451 of the cathode-side cover part 450 on the gap 40 side can be reduced. Therefore, the acoustic waves 61a reflected by the side face 451 back to a discharge region can be reduced. In addition, since the volume occupied by the cathode-side acoustic absorbing member 470 in the gap 40 increases, an acoustic absorbing effect is improved.

### 5. DESCRIPTION OF EMBODIMENT 2

Next, the chamber body 131 of Embodiment 2 will be described. Any component same as that described above is denoted by the same sign, and any redundant description thereof is omitted unless specific description is needed. Further, in some drawings, a part of members may be omitted or simplified for clarity, and a reference sign is given only to a part of the same components, and the reference sign is omitted in some cases.

### 5.1 Configuration

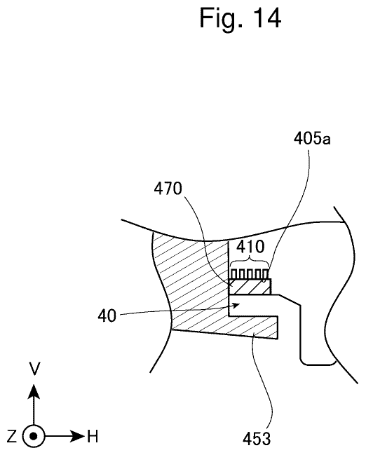

FIG. 14 is a sectional view perpendicular to the optical axis of the laser beam around the cathode 400 according to Embodiment 2. The chamber body 131 of the present embodiment differs from those of the other embodiments in that a slit structure 410 is provided on the surface 405a of the first base part 405 where the cathode-side acoustic absorbing member 470 is disposed. Slits extend along the cathode-side acoustic absorbing member 470 in the Z direction and in the H direction. The slits preferably have a depth of 1.7 mm to 2 mm.

Note that a structure provided on the surface 405a may not be the regular slit structure 410, and may be a structure having ruggedness of random depths.

### 5.2 Effect

Since the acoustic waves 61a transmitted through the cathode-side acoustic absorbing member 470 are irregularly reflected by the rugged structure provided in the first base part 405, the acoustic waves 61a are less likely to strengthen each other as compared with a case where the surface 405a of the base part 401 is planar. Therefore, it is possible to suppress occurrence of a disturbance in a laser gas distribution in the discharge space.

### 6. DESCRIPTION OF EMBODIMENT 3

Next, the chamber body 131 of Embodiment 3 will be described. Any component same as that described above is denoted by the same sign, and any redundant description thereof is omitted unless specific description is needed. Further, in some drawings, a part of members may be omitted or simplified for clarity, and a reference sign is given only to a part of the same components, and the reference sign is omitted in some cases.

### 6.1 Configuration

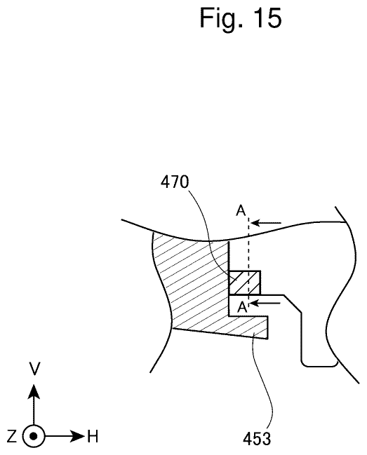

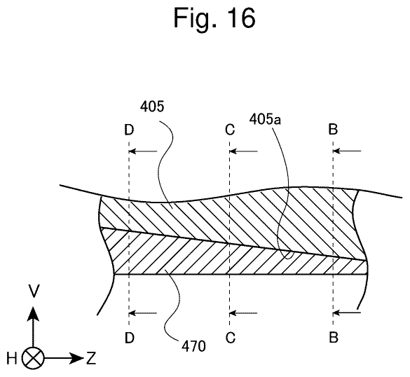

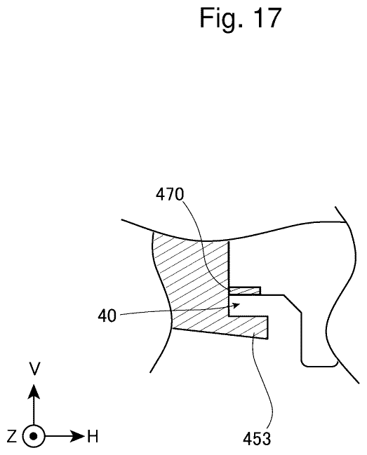

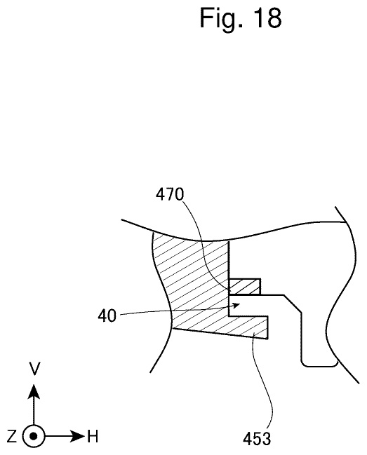

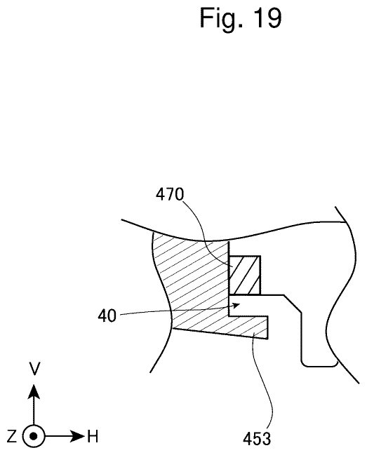

FIG. 15 is a sectional view perpendicular to the optical axis of the laser beam around the cathode 400 according to Embodiment 3. FIG. 16 is a sectional view taken along an A-A line indicated by arrows in FIG. 15. That is, FIG. 16 is a diagram illustrating a thickness relation between the cathode-side acoustic absorbing member 470 and the first base part 405 where the cathode-side acoustic absorbing member 470 is disposed. FIG. 17 is a sectional view taken along a B-B line indicated by arrows in FIG. 16. FIG. 18 is a sectional view taken along a C-C line indicated by arrows in FIG. 16. FIG. 19 is a sectional view taken along a D-D line indicated by arrows in FIG. 16. In the present embodiment, a thickness in the V direction of the first base part 405 where the cathode-side acoustic absorbing member 470 is disposed increases from the D-D side toward the B-B side in the Z direction. A thickness of the cathode-side acoustic absorbing member 470 in the V direction decreases from the D-D side toward the B-B side in the Z direction.

### 6.2 Effect

A phase of the acoustic waves 61a reflected from the first base part 405 can be shifted along the Z direction. Therefore, change in the density distribution of the laser gas is temporally dispersed so that the change in the density distribution of the laser gas at the time of the main discharge can be suppressed and unstable main discharge can be suppressed.

While the present embodiment illustrates an example in which the thickness in the V direction of the first base part 405 where the cathode-side acoustic absorbing member 470 is disposed and the thickness in the V direction of the cathode-side acoustic absorbing member 470 continuously change, the present invention is not limited thereto. For example, the thickness may change stepwise.

### 7. DESCRIPTION OF EMBODIMENT 4

Next, the chamber body 131 of Embodiment 4 will be described. Any component same as that described above is denoted by the same sign, and any redundant description thereof is omitted unless specific description is needed. Further, in some drawings, a part of members may be omitted or simplified for clarity, and a reference sign is given only to a part of the same components, and the reference sign is omitted in some cases.

### 7.1 Configuration

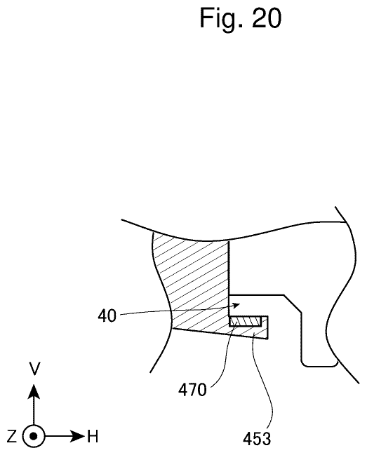

FIG. 20 is a sectional view perpendicular to the optical axis of the laser beam around the cathode 400 according to Embodiment 4. The chamber body 131 of the present embodiment differs from those of the other embodiments in that the cathode-side acoustic absorbing member 470 is disposed on the surface of the base facing part 453 on the base part 401 side.

### 7.2 Effect

The acoustic waves 61a propagated to the gap 40 are absorbed by the cathode-side acoustic absorbing member 470. Therefore, magnitude of the reflected waves 61b is reduced, and decline of stability of the laser beam output from the gas laser apparatus 100 is suppressed.

### 8. DESCRIPTION OF EMBODIMENT 5

Next, the chamber body 131 of Embodiment 5 will be described. Any component same as that described above is denoted by the same sign, and any redundant description thereof is omitted unless specific description is needed. Further, in some drawings, a part of members may be omitted or simplified for clarity, and a reference sign is given only to a part of the same components, and the reference sign is omitted in some cases.

### 8.1 Configuration

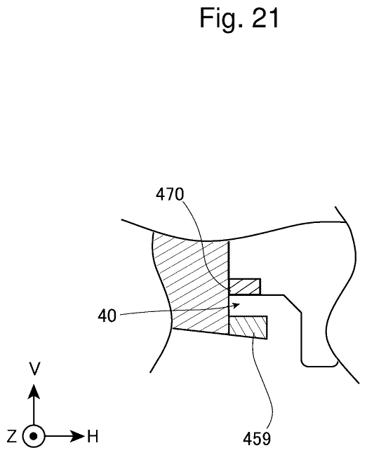

FIG. 21 is a sectional view perpendicular to the optical axis of the laser beam around the cathode 400 according to Embodiment 5. The chamber body 131 of the present embodiment differs from those of the other embodiments in that the base facing part 453 of the cathode-side cover part 450 is replaced with a conductive acoustic absorbing member 459. Note that the entire base facing part 453 may not be replaced with the conductive acoustic absorbing member 459, and a part of the surface of the base facing part 453 on the anode 500 side may include the conductive acoustic absorbing member 459.

### 8.2 Effect

Since the acoustic waves 61a reflected by the surface of the cathode-side cover part 450 on the anode side can be attenuated, the change in the density distribution of the laser gas can be suppressed, and the main discharge can be suppressed from becoming unstable.

### 9. DESCRIPTION OF EMBODIMENT 6

The chamber body 131 of Embodiment 6 will be described. Any component same as that described above is denoted by the same sign, and any redundant description thereof is omitted unless specific description is needed. Further, in some drawings, a part of members may be omitted or simplified for clarity, and a reference sign is given only to a part of the same components, and the reference sign is omitted in some cases.

### 9.1 Configuration

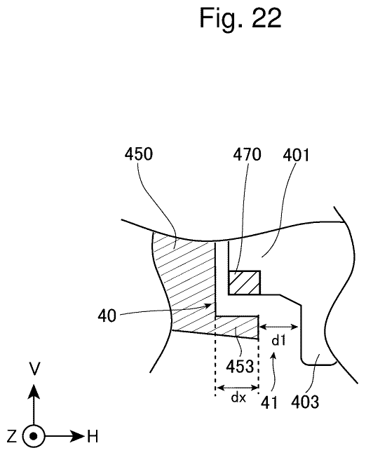

FIG. 22 is a sectional view perpendicular to the optical axis of the laser beam around the cathode 400 in the present embodiment. The chamber body 131 of the present embodiment differs from that of Embodiment 1 in that the cathode-side acoustic absorbing member 470 is exposed in the V direction. In this case, it is preferable that the distance d1 between the base facing part 453 and the discharge part 403, which is a size of the entrance 41 of the gap 40, be longer than 0.4 mm and be shorter than 5 mm, that a part of the cathode-side cover part 450 be separated from the base part 401 in the H direction, and that a length dx of the gap 40 in the H direction be equal to or longer than d1.

### 9.2 Effect

The reflection of the acoustic waves 61a on the surface of the base facing part 453 on the anode 500 side can be reduced. Further, it is possible to prevent the laser gas distribution in the discharge space in the vicinity of the discharge part 403 from being disturbed. Further, even in a structure in which the cathode-side acoustic absorbing member 470 is exposed in the V direction, since the gap 40 is extended in the H direction and the V direction, the acoustic waves 61a entering the gap 40 are more likely reflected by the cathode-side cover part 450, and the acoustic waves 61a easily reach the cathode-side acoustic absorbing member 470.

### 10. DESCRIPTION OF EMBODIMENT 7

The chamber body 131 of Embodiment 7 will be described. Any component same as that described above is denoted by the same sign, and any redundant description thereof is omitted unless specific description is needed. Further, in some drawings, a part of members may be omitted or simplified for clarity, and a reference sign is given only to a part of the same components, and the reference sign is omitted in some cases.

For the chamber body 131 of Embodiment 7, the configuration on the anode 500 side will be mainly described, and the configuration on the cathode 400 side may be that on the cathode 400 side of any one of the other embodiments and the modifications thereof.

### 10.1 Configuration

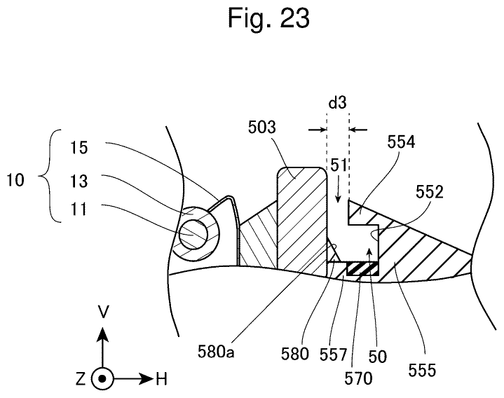

FIG. 23 is a sectional view perpendicular to the optical axis of the laser beam around the anode 500 according to Embodiment 7. The chamber body 131 of the present embodiment differs from those of the other embodiments in that a gap 50 is provided between the anode 500 and the cover member 555 since the cover member 555 is separated from the anode 500. The gap 50 is a generally L-shaped space surrounded by an entrance 51 of the gap 50 provided between a side face of the anode 500 and a cover base facing part 554, the cover base facing part 554, a side face 552 of the cover member 555, a cover base part 557, and the side face of the anode 500. Such a gap 50 can suppress assembly of the anode 500 and the cover member 555 from becoming impossible due to interference caused by dimensional errors in manufacturing of the anode 500 and the cover member 555. The cover member 555 defining the gap 50 covers the anode 500 from the side.

The cover base facing part 554 of the cover member 555 is separated from the cover base part 557 which is a part of the cover member 555 in the V direction, and protrudes in the H direction from the side face 552 toward the side face of the anode 500. The cover base facing part 554 is separated from the anode 500 in the H direction. The cover base facing part 554 extends in the Z direction and has substantially the same length as the anode 500 in the Z direction.

A distance d3 between the cover base facing part 554 and the anode 500 is preferably longer than 0.4 mm and is shorter than 5 mm.

The chamber body 131 of the present embodiment differs from those of the other embodiments and the modifications thereof in that the chamber body 131 further includes an anode-side acoustic absorbing member 570 provided in the gap 50 between the cover base part 557 and the cover base facing part 554. The configuration and the material of the anode-side acoustic absorbing member 570 are the same as the configuration and the material of the cathode-side acoustic absorbing member 470.

Further, the chamber body 131 according to the present embodiment differs from those of the other embodiments and the modifications thereof in that it includes an anode-side inclined part 580. The anode-side inclined part 580 includes an anode-side inclined surface 580a. The anode-side inclined surface 580a is disposed at least partially in a space closer to the cover base part 557 than the cover base facing part 554 in the V direction and closer to the anode 500 than the cover base facing part 554 in the H direction. The anode-side inclined surface 580a broadens to the opposite side with respect to the anode 500 as it is closer to the cover base part 557 from the anode 500 along the V direction, and extends in the Z direction.

While the gap 50 is provided on the downstream side of the anode 500 since the preionization electrode 10 is provided on the upstream side of the anode 500 in the present embodiment, the gap 50 may be provided on the upstream side of the anode 500. The anode-side inclined part 580 and the anode-side inclined surface 580a similar to those on the downstream side may be provided in the gap on the upstream side of the anode 500 as well.

### 10.2 Effect

In the chamber body 131 of the present embodiment, since the acoustic waves 61a reflected by the anode-side inclined surface 580a can be reflected by the surface of the cover base facing part 554 on the ground plate 137 side, the acoustic waves 61a can be guided to the gap 50, and the acoustic waves 61a can be absorbed by the anode-side acoustic absorbing member 570 disposed in the gap 50. Therefore, the reflected waves 61b returning to the discharge space can be reduced, and the chamber body 131 of the gas laser apparatus 100 capable of outputting the laser beam having the stable pulse energy even at the high repetition frequency can be realized.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined.

For example, while an example in which the inclined surface 480a is a planar surface in the chamber body 131 has been illustrated, the present invention is not limited thereto. For example, the inclined surface 480a may be curved. In addition, while an example in which the angle θ for the inclined part 480 satisfies Expression (1) has been illustrated, the angle θ may not satisfy Expression (1). Further, while an example in which the inclined part 480 is in contact with the discharge part 403 and the second base part 407 has been illustrated, the present invention is not limited thereto. The inclined surface 480a of the inclined part 480 may be at least partially disposed in a space closer to the base part 401 than the base facing part 453 in the V direction and closer to the discharge part 403 than the base facing part 453 in the H direction, and the inclined part 480 may be separated from at least one of the discharge part 403 and the second base part 407.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A chamber device of a gas laser apparatus, comprising:
a chamber body;
an anode that is disposed in an internal space of the chamber body and longitudinally extends along a predetermined direction;
a cathode that is disposed in the internal space in a first direction of facing and separating from the anode, longitudinally extends along the predetermined direction, and includes a base part and a discharge part having a width smaller than a width of the base part in a second direction perpendicular to the predetermined direction and the first direction and protruding from the base part toward the anode;
a cathode-side cover part that includes a base facing part separated from the base part and overlapping a part of the base part in the first direction and separated from the discharge part and overlapping the discharge part in the second direction, and covers a part of the base part;
a cathode-side acoustic absorbing member disposed in a space between the cathode-side cover part and the base part; and
an inclined part including an inclined surface that is positioned at least partially in a space closer to the base part than the base facing part in the first direction and closer to the discharge part than the base facing part in the second direction, broadens to an opposite side with respect to the discharge part as the inclined surface is closer to the base part from the discharge part, and extends in the predetermined direction.

2. The chamber device of a gas laser apparatus according to claim 1, wherein
an acute angle θ formed between the inclined surface and a surface of the base part facing the base facing part satisfies Expression (1) below, when a distance in the second direction between a position farthest from the discharge part on the inclined surface positioned between the discharge part and the cathode-side cover part, when the inclined surface is viewed from the anode along the first direction, and the base facing part is defined as a, and a distance in the first direction between the base facing part and the base part facing the base facing part is defined as b.
$$\frac{1}{2} {tan}^{- 1} ( \frac{a}{b} ) < θ < 90 ° - \frac{1}{2} {tan}^{- 1} ( \frac{a}{b} ) \qquad ( 1 )$$

3. The chamber device of a gas laser apparatus according to claim 1, wherein
in the base part, a distance in the first direction between a surface facing the base facing part and a position closest to the anode on the inclined surface is equal to or shorter than the distance b in the first direction.

4. The chamber device of a gas laser apparatus according to claim 1, wherein
at least one of the discharge part and the base part and the inclined part are integrated.

5. The chamber device of a gas laser apparatus according to claim 1, wherein
the inclined part is separate from the cathode.

6. The chamber device of a gas laser apparatus according to claim 5, wherein
the inclined part is a triangular prism with a bottom surface in a shape of a right-angled triangle.

7. The chamber device of a gas laser apparatus according to claim 1, wherein
the inclined part is disposed on both sides of the discharge part in the second direction.

8. The chamber device of a gas laser apparatus according to claim 1, wherein
an edge of the base facing part on a base part side is chamfered.

9. The chamber device of a gas laser apparatus according to claim 1, wherein
a distance between an end face of the base facing part on a discharge part side and the inclined surface is equal to or longer than a distance between the end face of the base facing part on the discharge part side and the discharge part.

10. The chamber device of a gas laser apparatus according to claim 1, wherein
the cathode-side acoustic absorbing member is disposed on the base part.

11. The chamber device of a gas laser apparatus according to claim 10, wherein
a rugged structure is provided at a position where the cathode-side acoustic absorbing member of the base part is disposed.

12. The chamber apparatus of a gas laser apparatus according to claim 11, wherein
the rugged structure includes a plurality of slits arranged in parallel.

13. The chamber device of a gas laser apparatus according to claim 1, wherein
at least a part of the cathode-side cover part is separated from the base part in the second direction.

14. The chamber device of a gas laser apparatus according to claim 1, wherein
the cathode-side acoustic absorbing member is disposed in the base part facing the base facing part, a thickness of the base part in the first direction at a position where the cathode-side acoustic absorbing member is disposed increases from one side to another side in the predetermined direction, and a thickness of the cathode-side acoustic absorbing member in the first direction decreases from the one side to the other side in the predetermined direction.

15. The chamber device of a gas laser apparatus according to claim 1, wherein
the cathode-side acoustic absorbing member is disposed on a surface of the base facing part on a base part side.

16. The chamber device of a gas laser apparatus according to claim 1, wherein
a surface of the cathode-side cover part on an anode side includes a conductive acoustic absorbing member.

17. The chamber device of a gas laser apparatus according to claim 1, further comprising:
a ground plate that is disposed in the internal space and supports the anode from a side opposite to the cathode;
an anode-side cover part including a cover base part in contact with the anode, and a cover base facing part that is separated from the cover base part and overlaps a part of the cover base part in the first direction and is separated from the anode and overlaps the anode in the second direction;
an anode-side acoustic absorbing member disposed in a space between the cover base facing part and the cover base part; and
an anode-side inclined part including an anode-side inclined surface that is positioned at least partially in a space closer to the cover base part than the cover base facing part in the first direction and closer to the anode than the cover base facing part in the second direction, broadens to an opposite side with respect to the anode as the anode-side inclined surface is closer to the ground plate from the anode, and extends in the predetermined direction.

18. A gas laser apparatus comprising a chamber device configured to output a laser beam,
the chamber device including:
a chamber body;
an anode that is disposed in an internal space of the chamber body and longitudinally extends along a predetermined direction;
a cathode that is disposed in the internal space in a first direction of facing and separating from the anode, longitudinally extends along the predetermined direction, and includes a base part and a discharge part having a width smaller than a width of the base part in a second direction perpendicular to the predetermined direction and the first direction and protruding from the base part toward the anode;
a cathode-side cover part that includes a base facing part separated from the base part and overlapping a part of the base part in the first direction and separated from the discharge part and overlapping the discharge part in the second direction, and covers the base part;
a cathode-side acoustic absorbing member disposed in a space between the cathode-side cover part and the base part; and
an inclined part including an inclined surface that is disposed at least partially in a space closer to the base part than the base facing part in the first direction and closer to the discharge part than the base facing part in the second direction, broadens to an opposite side with respect to the discharge part as the inclined surface is closer to the base part from the discharge part, and extends in the predetermined direction.

19. An electronic device manufacturing method comprising:
generating a laser beam with a gas laser apparatus including a chamber device including
a chamber body,
an anode that is disposed in an internal space of the chamber body and longitudinally extends along a predetermined direction,
a cathode that is disposed in the internal space in a first direction of facing and separating from the anode, longitudinally extends along the predetermined direction, and includes a base part and a discharge part having a width smaller than a width of the base part in a second direction perpendicular to the predetermined direction and the first direction and protruding from the base part toward the anode,
a cathode-side cover part that includes a base facing part separated from the base part and overlapping a part of the base part in the first direction and separated from the discharge part and overlapping the discharge part in the second direction, and covers the base part,
a cathode-side acoustic absorbing member disposed in a space between the cathode-side cover part and the base part, and
an inclined part including an inclined surface that is disposed at least partially in a space closer to the base part than the base facing part in the first direction and closer to the discharge part than the base facing part in the second direction, broadens to an opposite side with respect to the discharge part as the inclined surface is closer to the base part from the discharge part, and extends in the predetermined direction;
outputting the laser beam to an exposure apparatus; and
exposing a photosensitive substrate to the laser beam within the exposure apparatus to manufacture an electronic device.
